(19) United States
(12) Patent Application Publication
(10) Pub. No.: US 2024/0090271 A1
(43) Pub. Date: Mar. 14, 2024

(54) DISPLAY PANEL, PREPARATION METHOD THEREFOR, AND TERMINAL

(71) Applicant: Honor Device Co., Ltd., Shenzhen (CN)

(72) Inventors: Yabin An, Shenzhen (CN); Haiming He, Shenzhen (CN)

(73) Assignee: Honor Device Co., Ltd., Shenzhen (CN)

(21) Appl. No.: 18/272,289

(22) PCT Filed: Apr. 15, 2022
(86) PCT No.: PCT/CN2022/087163

§ 371 Date: Jul. 13, 2023

(30) Foreign Application Priority Data
Jul. 2, 2021 (CN) 202110750493.0

(51) Int. Cl. H10K 59/122; H10K 50/17; H10K 59/12; H10K 59/35

(52) U.S. Cl. CPC H10K 59/122; H10K 50/17; H10K 59/1201; H10K 59/35

(57) ABSTRACT

Embodiments of this application provide a display panel, a preparation method therefor, and a terminal. The display panel includes a substrate, a first organic light emitting diode and a second organic light emitting diode that are adjacent, a pixel define layer, and a common layer. The first organic light emitting diode and the second organic light emitting diode respectively include a first anode and a second anode. The common layer includes a first part located on the first anode, a second part located on the second anode, and a blocking part that is located on the pixel define layer and that is formed due to the pixel define layer.

### CROSS-REFERENCE TO RELATED APPLICATIONS

This application is a national stage of International Application No. PCT/CN2022/087163 filed on Apr. 15, 2022, which claims priority to Chinese Patent Application No. 202110750493.0 filed on Jul. 2, 2021. The disclosures of both of the aforementioned application are hereby incorporated by reference in their entireties.

### TECHNICAL FIELD

This application relates to the field of display technologies, and in particular, to a display panel, and a preparation method therefor, and a terminal.

### BACKGROUND

In an organic light emitting diode (Organic Light Emitting Diode, OLED) display panel, a hole inject layer, a hole transfer layer, and the like are all common layers (Common Layer), and cover all subpixel areas and an interval area between subpixels. When an OLED device works, because common layers of the subpixels are connected, carriers are transversely conducted in these common layers, so that a lateral current leakage occurs at the common layer. As a result, when a subpixel is lit, subpixels adjacent to the subpixel are easily affected by the subpixel, and a color crosstalk phenomenon occurs.

### SUMMARY

According to a first aspect, this application provides a display panel, including:
a substrate;
a first subpixel and a second subpixel that are adjacent and that are disposed on the substrate, where the first subpixel includes a first organic light emitting diode, the second subpixel includes a second organic light emitting diode, the first organic light emitting diode includes a first anode located on the substrate, and the second organic light emitting diode includes a second anode located on the substrate;
a pixel define layer, located on the substrate, on the first anode, and on the second anode, where the pixel define layer has pixel defining holes that expose the first anode and the second anode; and
a common layer, where the common layer includes a first part located on the first anode, a second part located on the second anode, and a blocking part that is located on the pixel define layer and that is formed due to the pixel define layer; where
the first part forms a portion of the first organic light emitting diode, the second part forms a portion of the second organic light emitting diode, and the first part and the second part are insulated and spaced from each other by using the blocking part.

In this way, according to a structural design of the pixel define layer, a lateral connection between at least parts of the common layer is blocked, so as to prevent occurrence of a color crosstalk phenomenon.

In some embodiments of this application, the pixel define layer includes a top surface away from the substrate and a side surface connected to the top surface. The side surface includes a recessed part, so that the blocking part is formed at the common layer. That is, the pixel define layer has a recessed part that breaks continuity of the common layer.

In some embodiments of this application, the recessed part is obtained by forming an under cut (Under Cut) at the pixel define layer.

In some embodiments of this application, the pixel define layer includes a first pixel define layer and a second pixel define layer that are successively stacked in a direction away from the substrate. The recessed part is formed at the first pixel define layer, and the top surface is formed at the second pixel define layer.

In some embodiments of this application, the top surface includes a curved surface connected to the side surface, and an included angle between the curved surface and a surface of the substrate ranges from 5 degrees˜30 degrees. Therefore, when the included angle θ ranges from 5 degrees˜30 degrees, in one aspect, it can implement slow lapping of cathodes without disconnection, and in another aspect, the organic light emitting diode can further obtain a larger divergence angle, so as to prevent occurrence of a color cast and a low gray-scale color cast.

In some embodiments of this application, the display panel includes a hole inject layer, a hole transfer layer, an organic light emitting layer, a hole block layer, and an electron transfer layer that are successively stacked in a direction away from the substrate, and the common layer includes one or more of the hole inject layer, the hole transfer layer, the hole block layer, and the electron transfer layer.

In some embodiments of this application, the hole inject layer is in direct contact with the pixel define layer, the first anode, and the second anode. A height from a surface that is of the first pixel define layer and that is away from the substrate to a surface that is of the first anode and that is away from the substrate is defined as h. A sum of heights of the hole inject layer and the hole transfer layer is defined as h_{L}. A sum of heights of the hole inject layer, the hole transfer layer, the organic light emitting layer, the hole block layer, and the electron transfer layer is defined as h_{H}, where h_{L}≤h≤h_{H}. That is, the blocked common layer includes at least the hole inject layer and the hole transfer layer.

In some embodiments of this application, the organic light emitting layer includes a first organic light emitting layer, an electron-hole pair secondary generation layer, and a second organic light emitting layer that are successively stacked in a direction away from the substrate. The common layer includes the electron-hole pair secondary generation layer.

In some embodiments of this application, the display panel further includes a cathode layer located on a side that is of the common layer and that is away from the substrate. The cathode layer is a continuous film layer and is not blocked by the pixel define layer.

According to a second aspect, this application provides a display panel, including:
a substrate;
a plurality of organic light emitting diodes that are disposed on the substrate at intervals, where each organic light emitting diode includes one anode;
a pixel define layer, located on the substrate and on the anode, where the pixel define layer has a plurality of pixel defining holes, and each pixel defining hole exposes one anode; and
a common layer, including a part on the anode and a part on the pixel define layer; where
the pixel define layer includes a first pixel define layer and a second pixel define layer that are successively stacked in a direction away from the substrate, and
a side surface of the first pixel define layer includes a recessed part that is recessed relative to the second pixel define layer, so that a part that is of the common layer and that is on the anode is blocked from a part that is of the common layer and that is on the pixel define layer.

According to a second aspect, this application provides a terminal, including the foregoing display panel.

Because the terminal includes the foregoing display panel, the terminal also has an advantage of avoiding a color crosstalk phenomenon.

According to a third aspect, this application provides a preparation method for a display panel, where the method includes:
forming a plurality of anodes arranged in an array on a substrate, where the plurality of anodes include a first anode and a second anode that are adjacent;
forming a pixel define layer on the substrate and the plurality of anodes, where the pixel define layer has pixel defining holes that expose the first anode and the second anode; and
forming a common layer on the pixel define layer and the plurality of anodes, where the common layer includes a first part on the first anode, a second part on the second anode, and a blocking part that is on the pixel define layer and that is formed due to the pixel define layer, and the first part and the second part are insulated and spaced from each other by using the blocking part; where
the first part is used to form a part of a first organic light emitting diode, the second part is used to form a part of a second organic light emitting diode, the first organic light emitting diode includes a first anode, and the second organic light emitting diode includes a second anode.

In some embodiments of this application, the pixel define layer includes a top surface away from the substrate and a side surface connected to the top surface. Forming the pixel define layer includes forming a recessed part on the side surface.

In some embodiments of this application, forming the pixel define layer includes successively forming a first pixel define layer and a second pixel define layer that are stacked in a direction away from the substrate. The recessed part is formed at the first pixel define layer, and the top surface is formed at the second pixel define layer.

In some embodiments of this application, the preparation method includes successively forming a hole inject layer, a hole transfer layer, an organic light emitting layer, a hole block layer, and an electron transfer layer that are stacked in a direction away from the substrate; and forming the common layer includes forming one or more of the hole inject layer, the hole transfer layer, the hole block layer, and the electron transfer layer.

In some embodiments of this application, forming the organic light emitting layer includes successively forming a first organic light emitting layer, an electron-hole pair secondary generation layer, and a second organic light emitting layer in a direction away from the substrate. Forming the common layer includes forming the electron-hole pair secondary generation layer.

### BRIEF DESCRIPTION OF THE DRAWINGS

FIG. 1 is a schematic diagram of a structure of a terminal according to some embodiments of this application;

FIG. 2 is a schematic diagram of a structure of a display panel in FIG. 1;

FIG. 3 is a schematic diagram of a structure of OLEDs according to some embodiments of this application;

FIG. 4 is another schematic diagram of a structure of OLEDs according to some embodiment of this application;

FIG. 5 is a schematic cross-sectional diagram of a display panel according to some embodiments of this application;

FIG. 6 is a flowchart of a preparation method for a display panel according to some embodiments of this application;

FIG. 7 is a schematic cross-sectional diagram of forming a planarization layer in the method in FIG. 6;

FIG. 8 is a schematic cross-sectional diagram of forming an anode on the planarization layer shown in FIG. 7;

FIG. 9 is a schematic cross-sectional diagram of forming a first material layer, a hard mask layer, and a patterned photoresist layer on the structure shown in FIG. 8;

FIG. 10 is a schematic cross-sectional diagram of forming a patterned hard mask layer by using the patterned photoresist layer shown in FIG. 9 as a mask;

FIG. 11 is a schematic cross-sectional diagram of forming a first pixel define layer by using the patterned hard mask layer shown in FIG. 10 as a mask;

FIG. 12 is a schematic cross-sectional diagram after the patterned hard mask layer shown in FIG. 11 is removed; and

FIG. 13 is a schematic cross-sectional diagram of forming a second pixel define layer on the first pixel define layer shown in FIG. 12.

### DESCRIPTION OF REFERENCE SIGNS OF MAIN ELEMENTS

Terminal 100
Cover 10
Display panel 20
Pixel 22
Subpixel 222
First subpixel 2221
Second subpixel 2222
Organic light emitting diode 24
Anode 241
First anode 2411
Second anode 2412
Hole inject layer 242
Hole transfer layer 243
Organic light emitting layer 244
First organic light emitting layer 2441
Second organic light emitting layer 2442
Electron-hole pair secondary generation layer 2443
Hole block layer 245
Electron transfer layer 246
Cathode 247
Capping layer 248
Lithium fluoride layer 249
Support structure 30
TFT backplane 40
Substrate 42
Driving circuit layer 44
Planarization layer 46
Pixel define layer 48
First pixel define layer 482
Side surface 4822
Recessed part 4824
Second pixel define layer 484
Top surface 4842
Included angle θ
Pixel defining hole 486
First material layer 52
Hard mask layer 54
Patterned photoresist layer 56
Patterned hard mask layer 58
Common layer 60
First part 61
Second part 62
Blocking part 63

This application is further described in the following specific implementations with reference to the accompanying drawings.

### DETAILED DESCRIPTION OF ILLUSTRATIVE EMBODIMENTS

The following describes technical solutions in embodiments of this application with reference to accompanying drawings in embodiments of this application.

An embodiment of this application provides a terminal. The terminal may be a product that has a display interface, such as a mobile phone, a display, a tablet computer, or an in-vehicle computer, and an intelligent display wearable product, such as a smartwatch or a smart band. The following uses an example in which the terminal is a mobile phone for description.

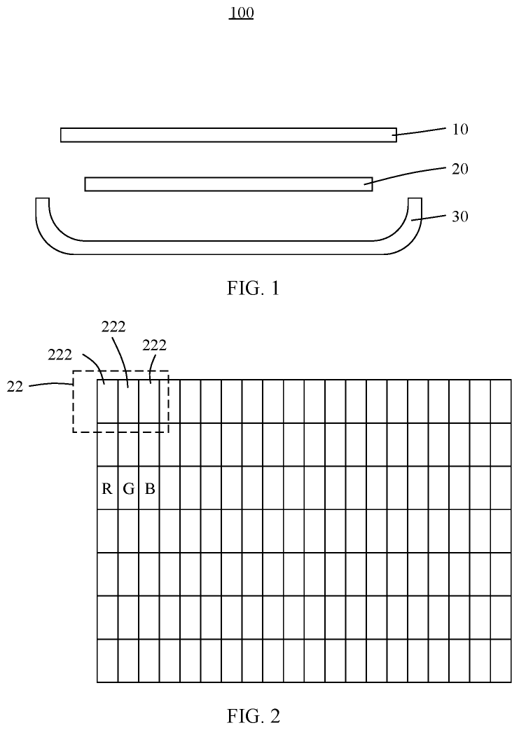

As shown in FIG. 1, the terminal 100 includes a cover 10, a display panel 20, and a support structure 30. The cover 10 defines a display surface of the terminal 100. The display panel 20 is used to display a picture. The support structure 30 is also referred to as a housing or a rear cover or a battery cover. The cover 10 and the support structure 30 cooperate to form an accommodating space (not shown in the figure), and the display panel 20 is located in the accommodating space between the cover 10 and the support structure 30. In addition, other functional parts/electronic components, such as a main board and a battery, may be installed in the accommodating space.

The following describes a structure of the display panel 20.

As shown in FIG. 2, the display panel 20 includes a plurality of pixels (Pixel) 22 arranged in an array. Each pixel 22 includes at least one subpixel 222 used to emit visible light. In FIG. 2, the first pixel 22 includes three subpixels 222, which are respectively a red-emitting display subpixel R, a green-emitting display subpixel G, and a blue-emitting display subpixel B.

In some embodiments of this application, the visible light emitted by the three subpixels 222 in the pixel 22 is cyan light, magenta light, and yellow light. Alternatively, in some other embodiments of this application, the pixel 22 includes four subpixels 222, and visible light emitted by the four subpixels 222 is red light, green light, blue light, and white light respectively. Alternatively, in some other embodiments of this application, the display panel 20 is a monochrome display panel, and subpixels 222 included in the display panel all emit visible light of a same color. For example, all subpixels in the display panel 20 are subpixels that emit green light. That is, a quantity of subpixels 222 in the pixel 22 and a combination of emitted light colors are not limited.

On this basis, to enable the foregoing subpixels 222 to emit visible light, in some embodiments of this application, the display panel 20 further includes a plurality of Organic Light Emitting Diodes (Organic Light Emitting Diode, OLED) 24. Each OLED 24 is corresponding to one subpixel 222, and each OLED 24 is located in a subpixel 222 corresponding to the OLED 24, so that the display panel 20 can implement self-illumination without the need for a backlight. The display panel 20 is an active matrix organic light emitting diode (active matrix organic light emitting diode, AMOLED) display panel, and has advantages such as a bright color, a high contrast ratio, and a fast response speed. In some embodiments, the display panel 20 is a flexible OLED display panel, has a bendable and deformable feature, and has great potential in a special-shaped display such as a bendable mobile phone and a curved display.

The following describes a disposition manner of the OLED 24 in the display panel 20 by using examples.

Example 1 of the OLED 24

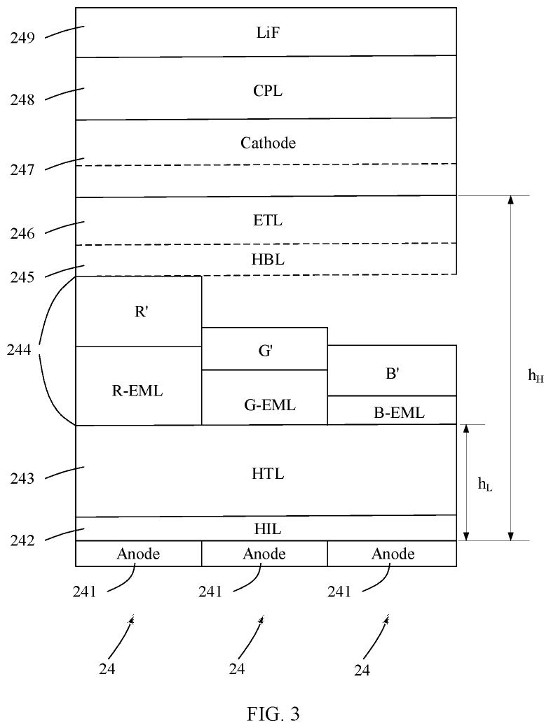

Three OLEDs 24 are schematically drawn in FIG. 3. As shown in FIG. 3, each OLED 24 includes an organic light emitting layer 244, and an anode (Anode) 241 and a cathode (Cathode) 247 that are located on opposite sides of the organic light emitting layer 244. Anodes 241 of the OLEDs 24 are independent of each other, and cathodes 247 of the plurality of OLEDs 24 are an integrated layer.

In some embodiments of this application, a material of the anode 241 may be a metal material, for example, aluminum (Al), magnesium (Mg), argentum (Ag), or magnesium/argentum Mg/Ag. A proportion of Mg in magnesium/argentum (Mg/Ag) is, for example, between 8%˜12%. A material of the cathode 247 may be a transparent or semi-transparent conductive material, for example, indium tin oxide (Indium Tin Oxide, ITO) or indium zinc oxide (Indium Zinc Oxide, IZO). In this case, the cathode 247 transmits light, and a light transmittance of the anode 241 is very small. Therefore, light emitted by the OLED 24 exits from a side on which the cathode 247 is located. In this case, the OLED 24 is a top-emission light emitting device.

In some other embodiments of this application, the material of the anode 241 may be the foregoing transparent conductive material, and the material of the cathode 247 is the foregoing metal material. In this case, the anode 241 transmits light, and a light transmittance of the anode 247 is very small. Therefore, light emitted by the OLED 24 exits from a side on which the cathode 241 is located. In this case, the OLED 24 is a bottom-emission light emitting device.

Based on this, after a voltage is applied to the anode 241 and the cathode 247 on two sides of the organic light emitting layer 244, holes are injected from the anode 241, electrons are injected from the cathode 247, and carriers in the anode 241 and the cathode 247 are combined in the organic light emitting layer 244 to be quenched, so that the organic light emitting layer 244 emits light wave radiation. In this case, the OLED 24 emits light, and the display panel 20 having the plurality of OLEDs 24 displays a picture. In a same pixel 22, materials of organic light emitting layers 244 of OLEDs 24 in different subpixels 222 are different, so that the OLEDs 24 in the different subpixels 222 emit visible light of different colors, for example, red light, green light, or blue light. In FIG. 3, an organic light emitting layer 244 of a subpixel 222 that emits red light includes a red prime (R prime, R′) and a red light emission layer (R-emission layer, R-EML). An organic light emitting layer 244 of a subpixel 222 that emits green light includes a green prime (G prime, G′) and a green light emission layer (G-emission layer, G-EML). An organic light emitting layer 244 of a subpixel 222 that emits blue light includes a blue prime (B prime, B′) and a blue light emission layer (B-emission layer, B-EML). Each anode 241 is corresponding to one subpixel 222.

In addition, to increase a probability that carriers in the anode 241 and the cathode 247 meet in the organic light emitting layer 244, so as to improve light emitting efficiency of the OLED 24, as shown in FIG. 3, the OLED 24 further includes a hole inject layer (Hole Inject Layer, HIL) 242, a hole transfer layer (Hole Transfer Layer, HTL) 243, a hole block layer (Hole Block Layer, HBL) 245, and an electron transfer layer (Electron Transfer Layer, ETL) 246. The hole inject layer 242 and the hole transfer layer 243 are located between the organic light emitting layer 244 and the anode 241. The hole block layer 245 and the electron transfer layer 246 are located between the organic light emitting layer 244 and the cathode 247, and are successively close to the cathode 247. That is, in FIG. 3, a stacking sequence of the film layers in the OLED 24 is successively the anode 241, the hole inject layer 242, the hole transfer layer 243, the organic light emitting layer 244, the hole block layer 245, the electron transfer layer 246, and the cathode 247.

In addition, as shown in FIG. 3, the OLED 24 further includes a capping layer (Capping Layer, CPL) 248 located above the cathode 247 and a lithium fluoride (LiF) layer 249 located above the capping layer 248. The capping layer 248 can improve microcavity light output efficiency of the OLED 24, and the lithium fluoride layer 249 can isolate ions, so as to improve light output efficiency.

Example 2 of the OLED 24

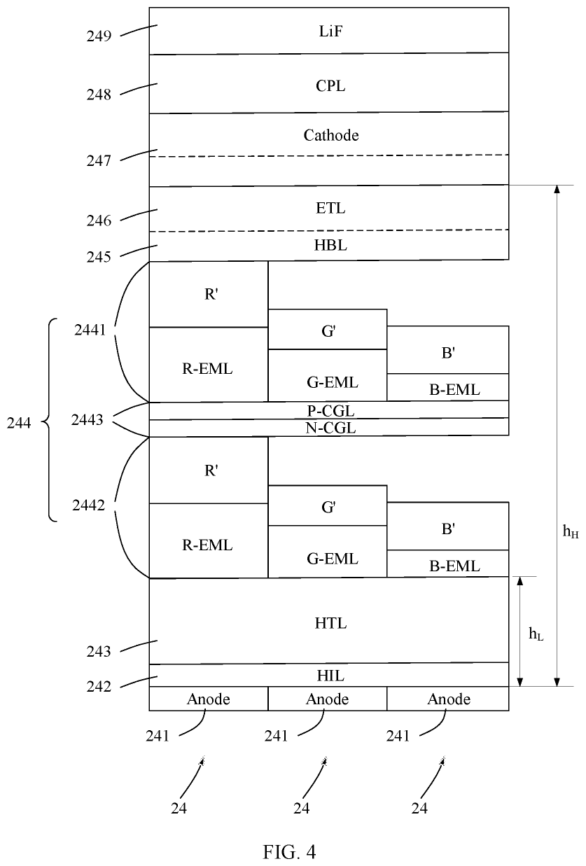

The OLED 24 in Example 2 is different from the OLED 24 in Example 1 in that: In Example 2, the OLED 24 includes a plurality of organic light emitting layers. FIG. 4 shows three OLEDs 24 in Example 2. As shown in FIG. 4, each OLED 24 in Example 2 includes a first organic light emitting layer 2441, a second organic light emitting layer 2442, and an electron-hole pair secondary generation layer 2443 located between the first organic light emitting layer 2441 and the second organic light emitting layer 2442. The electron-hole pair secondary generation layer 2443 is also called charge generation layer (Charge Generation Layer, CGL). The electron-hole pair secondary generation layer 2443 includes an electron secondary generation layer (N-CGL) and a hole secondary generation layer (P-CGL). The N-CGL is generally an organic sensitizer, and may include metal ytterbium (Yb), and when ytterbium is used in an electron sensitizer of organic matter, electron release from the organic matter can be promoted. The P-type material dopant in the P-CGL may be 2,2′-(1,3,4,5,6,8,9,10-octafluoro-2,7-diylidenepyrene) bismalononitrile doped in a weight ratio of 3%, and a chemical formula is as follows:

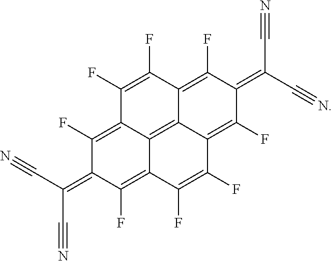 [SMILES: N#CC(C#N)=c1c(F)c2c(F)c(F)c3c(F)c(=C(C#N)C#N)c(F)c4c(F)c(F)c(c1F)c2c34]

That is, in FIG. 4, a stacking sequence of the film layers in the OLED 24 is successively the anode 241, the hole inject layer 242, the hole transfer layer 243, the first organic light emitting layer 2441, the electron-hole pair secondary generation layer 2443, the second organic light emitting layer 2442, the hole block layer 245, the electron transfer layer 246, and the cathode 247. Because more organic light emitting layers are connected in series in the OLED 24 of this structure, light output efficiency is improved, and brightness is higher at the same current density.

In the OLED 24 shown in FIG. 3, the hole inject layer 242, the hole transfer layer 243, the hole block layer 245, the electron transfer layer 246, the cathode 247, and the like are all common layers, and are functional layers simultaneously deposited on/covering the subpixels 222 (for example, R/G/B). For the OLED 24 shown in FIG. 4, the hole inject layer 242, the hole transfer layer 243, the hole block layer 245, the electron transfer layer 246, the cathode 247, and the electron-hole pair secondary generation layer 2443 are all common layers, and are functional layers simultaneously deposited/covered on the subpixels 222 (for example, R/G/B). If there is a lateral leakage between these common planes, a color crosstalk phenomenon occurs.

The following specifically describes how to resolve the color crosstalk problem caused by a lateral leakage between common layers in the display panel 20.

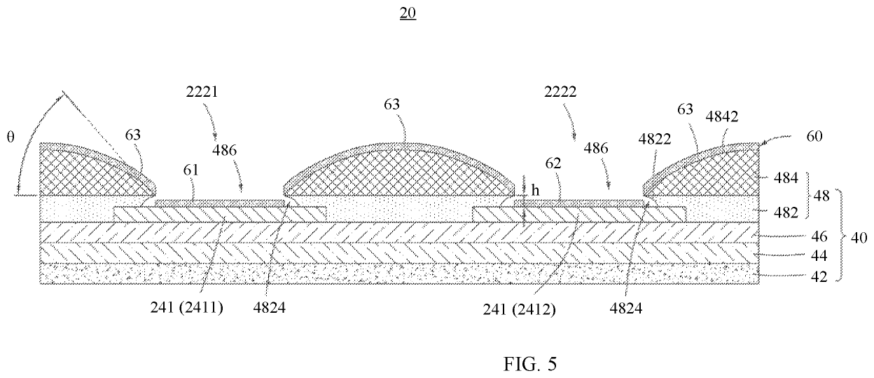

As shown in FIG. 5, the display panel 20 includes a thin film transistor (Thin Film Transistor, TFT) backplane 40. The TFT backplane 40 includes a substrate 42, a driving circuit layer 44 disposed on the substrate 42, a planarization (Planarization, PLN) layer 46 disposed on a side that is of the driving circuit layer 44 and that is away from the substrate 42, and a pixel define layer (Pixel Define Layer, PDL) 48.

The substrate 42 is used as a carrier substrate that carries layers such as the driving circuit layer 44 and the pixel define layer 48 that are located above the substrate 42, and a material of the substrate may be flexible materials such as polyethylene terephthalate (Polyethylene Terephthalate, PET) and polyimide (Polyimide, PI).

The driving circuit layer 44 includes, for example, pixel driving circuits arranged in an array (not shown in the figure). Each pixel driving circuit includes a plurality of driving TFTs, and the anode 241 of each OLED 24 is configured to be electrically connected to one driving TFT, so as to emit light under control of the driving TFT. The planarization layer 46 covers a plurality of driving TFTs, so as to flatten, insulate, and protect the driving TFTs on the substrate 42.

The pixel define layer 48 has a plurality of pixel defining holes 486 that expose anodes 241 of OLEDs 24 (two pixel defining holes are exemplarily illustrated in FIG. 5), and each pixel defining hole 486 exposes the anode 241 of one OLED 24. The pixel define layer 48 is located between two adjacent anodes 241 on the planarization layer 46, and at least partially covers the anodes 241. Each pixel defining hole 486 is corresponding to one subpixel 222. Each OLED 24 is corresponding to one pixel defining hole 486 (some film layers of the OLED 24 are omitted in FIG. 5, and only the anode 241 of the OLED 24 is drawn). The anode 241 of the OLED 24 may be electrically connected to the driving TFT through a via hole (not shown in the figure) provided on the planarization layer 46. The planarization layer 46 may provide a flat reflective surface for the anode 241.

For ease of description, the following defines that two adjacent subpixels 222 in one pixel 22 are respectively a first subpixel 2221 and a second subpixel 2222. It is defined that the OLED 24 in the first subpixel 2221 is a first OLED, and the OLED 24 in the second subpixel 2222 is a second OLED. It is defined that the anode 241 of the first OLED is a first anode 2411, and the anode 241 of the second OLED is a second anode 2412. The first anode 2411 and the second anode 2412 are disposed on the planarization layer 46 at an interval.

In some embodiments of this application, the structural design of the pixel define layer 48 enables at least one of the foregoing common layers 60 to be blocked by the pixel define layer 48. The blocked common layer 60 is divided into at least a first part 61 located on the first anode 2411, a second part 62 located on the second anode 2412, and a blocking part 63 that is located on the pixel define layer 48 and formed because of the pixel define layer 48. The first part 61 forms a part of the first OLED, the second part 62 forms a part of the second OLED, and the first part 61 and the second part 62 are insulated and spaced from each other by using the blocking part 63. In this way, the structural design of the pixel define layer 48 enables a lateral connection between at least parts of the common layers 60 to be blocked, so as to prevent occurrence of a color crosstalk phenomenon.

The following describes in detail a specific structure of the pixel define layer 48.

As shown in FIG. 5, the pixel define layer 48 includes a top surface 4842 that is away from the substrate 42 and a side surface 4822 connected to the top surface 4842. The side surface 4822 includes a recessed part 4824 that facilitates forming the blocking part 63 in the common layer 60. The recessed part 4824 is recessed along a direction in which an anode 241 of an OLED 24 points to an adjacent anode 241 of an OLED 24. That is, the pixel define layer 48 has a recessed part 4824 that breaks continuity of the common layer 60.

In some embodiments of this application, the recessed part 4824 is obtained by forming an under cut (Under Cut) in the pixel define layer 48. To form a desired undercut shape on the side surface 4822, the pixel define layer 48 may be composed of a plurality of layers of materials. In FIG. 5, the pixel define layer 48 includes a first pixel define layer 482 and a second pixel define layer 484 that are successively stacked in a direction away from the substrate 42. The recessed part 4824 is formed at the first pixel define layer 482. The top surface 4842 of the pixel define layer 48 is formed at the second pixel define layer 484, and the top surface 4842 of the pixel define layer 48 is a surface that is of the second pixel define layer 484 and that is away from the substrate 42. A chamfer formed by an undercut is present at the first pixel define layer 482, and the top surface 4842 of the second pixel define layer 484 includes a curved surface connected to the side surface 4822.

In some embodiments of this application, an included angle θ between the curved surface and an upper surface of the substrate 42 ranges from 5 degrees˜30 degrees. In other words, an included angle θ between the curved surface and an upper surface that is of the anode 241 of the OLED 24 and that is away from the substrate 42 ranges from 5 degrees˜30 degrees. In some embodiments, the included angle θ between the curved surface and the upper surface that is of the anode 241 and that is away from the substrate 42 is less than or equal to 15 degrees. If the included angle θ between the curved surface and the upper surface of the anode 241 of the OLED 24 is too small, the cathodes 247 of the OLEDs 24 may be disconnected in a lapping process. If the included angle θ is excessively large, it is unfavorable to divergence of emergent light of the OLED 24. Therefore, when the included angle θ ranges from 5 degrees˜30 degrees, in one aspect, it can implement slow lapping of the cathodes 247 without disconnection, and in another aspect, the OLED 24 can further obtain a larger divergence angle, so as to prevent occurrence of a color cast and a low gray-scale color cast.

In some embodiments of this application, in a preparation step of the second pixel define layer 484, a support pillar (not shown in the figure) that is located on the second pixel define layer 484 may be formed through one-time patterning by using a semi-mask process. The support pillar is used as the support structure 30, to effectively prevent, in a process of forming the OLED 24 through evaporation, an evaporation mask used to form functional layers of the OLED 24 light-emitting device through evaporation from contacting the display panel 20, so as to improve a product yield of the display panel 20.

In some embodiments of this application, the OLED 24 has the structure shown in FIG. 3. The common layers include the hole inject layer 242, the hole transfer layer 243, the hole block layer 245, the electron transfer layer 246, and the cathode 247. When the common layers are disposed in the pixel defining hole 486, the hole inject layer 242, the hole transfer layer 243, the organic light emitting layer 244, the hole block layer 245, and the electron transfer layer 246 are successively formed on the anode 241. At least one of the hole inject layer 242, the hole transfer layer 243, the hole block layer 245, and the electron transfer layer 246 is blocked, but the cathode 247 is not blocked.

Specifically, the hole inject layer 242 is directly in contact with the pixel define layer 48 and the anode 241 of the OLED 24. Upper surfaces that are of anodes 241 of two adjacent OLEDs 24 and that are away from the substrate 42 are basically located on a same plane. As shown in FIG. 5, a height between a surface that is of the first pixel define layer 482 and that is away from the substrate 42 and a surface that is of the anode 241 of the OLED 24 and that is away from the substrate 42 is defined as h. As shown in FIG. 3 and FIG. 4, a sum of heights of the hole inject layer 242 and the hole transfer layer 243 is defined as h_{L}. A sum of heights of the hole inject layer 242, the hole transfer layer 243, the organic light emitting layer 244, the hole block layer 245, and the electron transfer layer 246 is defined as h_{H}. h_{L}≤h≤h_{H}. That is, a height from the top of the first pixel define layer 482 to the upper surface of the anode 241 of the OLED 24 is h, and a height h_{L} of common layers (the hole inject layer 242 and the hole transfer layer 243) below at least the organic light emitting layer 244 is greater than or equal to h, so that at least the hole inject layer 242 and the hole transfer layer 243 are blocked. That is, the blocked common layers 60 include at least the hole inject layer 242 and the hole transfer layer 243. In addition, a height of film layers between the cathode 247 and the anode 241 is h_{H}, where h≤h_{H}, so that a cathode 247 layer formed by the cathodes 247 of all the OLEDs 24 is a continuous film layer and is not blocked by the pixel define layer 48.

In some other embodiments of this application, the OLED 24 has the structure shown in FIG. 4. The common layers include the hole inject layer 242, the hole transfer layer 243, the hole block layer 245, the electron transfer layer 246, the cathode 247, and the electron-hole pair secondary generation layer 2443. When the common layers are disposed in the pixel defining hole 486, the hole inject layer 242, the hole transfer layer 243, the first organic light emitting layer 2441, the electron-hole pair secondary generation layer 2443, the second organic light emitting layer 2442, the hole block layer 245, and the electron transfer layer 246 are successively formed on the anode 241. At least one of the hole inject layer 242, the hole transfer layer 243, the hole block layer 245, the electron transfer layer 246, and the electron-hole pair secondary generation layer 2443 is blocked, but the cathode 247 is not blocked.

Specifically, the hole inject layer 242 is directly in contact with the pixel define layer 48 and the anode 241 of the OLED 24. Upper surfaces that are of anodes 241 of two adjacent OLEDs 24 and that are away from the substrate 42 are basically located on a same plane. A height between a surface that is of the first pixel define layer 482 and that is away from the substrate 42 and a surface that is of the anode 241 of the OLED 24 and that is away from the substrate 42 is defined as h. A sum of heights of the hole inject layer 242 and the hole transfer layer 243 is defined as h_{L}. A sum of heights of the hole inject layer 242, the hole transfer layer 243, the organic light emitting layer 244 (including the first organic light emitting layer 2441, the electron-hole pair secondary generation layer 2443, and the second organic light emitting layer 2442), the hole block layer 245, and the electron transfer layer 246 is defined as h_{H}. Here, h_{L}≤h≤h_{H}. That is, a height from the top of the first pixel define layer 482 to the upper surface of the anode 241 of the OLED 24 is h, and a height h_{L} of common layers (the hole inject layer 242 and the hole transfer layer 243) below at least the organic light emitting layer 244 is greater than or equal to h, so that at least the hole inject layer 242 and the hole transfer layer 243 are blocked. That is, the blocked common layers 60 include at least the hole inject layer 242 and the hole transfer layer 243. In addition, a height of film layers between the cathode 247 and the anode 241 is h_{H}, where h≤h_{H}, so that a cathode 247 layer formed by the cathodes 247 of all the OLEDs 24 is a continuous film layer and is not blocked by the pixel define layer 48.

In some embodiments of this application, the height h from the top of the first pixel define layer 482 to the upper surface of the anode 241 of the OLED 24 ranges from 0.3 μm˜1 μm. If h is too small, the common layers 60 cannot be effectively blocked. If h is too large, an open (Open) circuit in the lapping of the cathodes 247 is easily caused.

In some embodiments of this application, the planarization layer 46 may be an organic material, for example, may be a PI organic material. Materials of the first pixel define layer 482 and the second pixel define layer 484 may be organic materials or inorganic materials. For example, the materials may be organosiloxane, silicon oxide (SiOx), silicon nitride (SiNx), metal oxide, or the like. In addition, it should be noted that a quantity of pixel define layers 48 is not limited, and the pixel define layers 48 may be a plurality of layers with more than two layers.

In conclusion, according to the structural design of the pixel define layer 48, at least a part of the common layers 60 of the OLEDs 24 in two adjacent subpixels 222 is blocked, so as to reduce lateral current leakage of the common layers 60 between the adjacent subpixels 222, thereby alleviating the problem of light-emitting crosstalk of the display panel 20 and improving display quality.

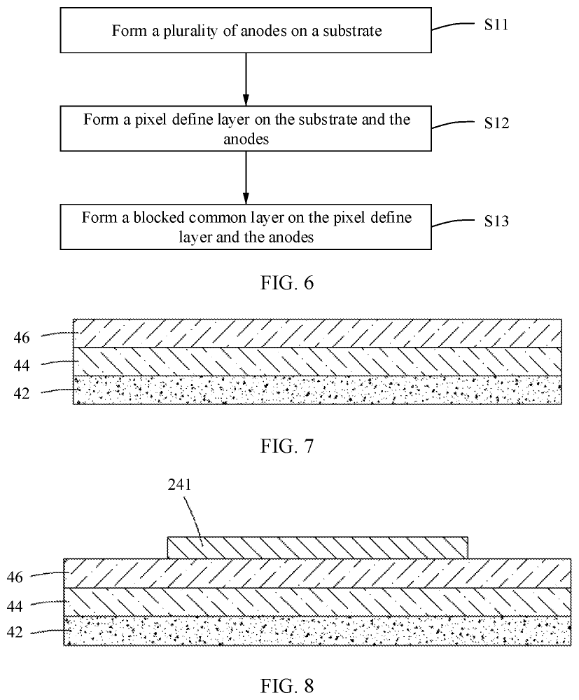

Some embodiments of this application further provide a preparation method for the foregoing display panel. According to different requirements, a sequence of steps of the preparation method may be changed, and some steps may be omitted or combined. As shown in FIG. 6, the preparation method includes the following steps.

Step S11: Form a plurality of anodes on a substrate.

Step S12: Form a pixel define layer on the substrate and the anode.

Step S13: Form blocked common layers on the pixel define layer and the anode.

The following describes the steps in detail.

Step S11: Form a plurality of anodes on a substrate.

In some embodiments of this application, before forming the anodes, the method further includes: successively forming a driving circuit layer and a planarization layer on the substrate.

As shown in FIG. 7, the planarization layer 46 is located on a surface that is of the driving circuit layer 44 and that is away from the substrate 42. The driving circuit layer 44 includes, for example, pixel driving circuits arranged in an array. Each pixel driving circuit includes a plurality of driving TFTs. The planarization layer 46 covers the plurality of driving TFTs. In some embodiments of this application, the planarization layer 46 is an organic material. For example, the planarization layer 46 may be formed by using a PI organic material.

As shown in FIG. 8, the anode 241 formed in step S11 is located on a surface that is of the planarization layer 46 and that is away from the substrate 42. Specifically, there are a plurality of anodes 241 formed in step S11, and the plurality of anodes 241 are spaced and arranged in an array on the planarization layer 46 (one is drawn exemplarily in FIG. 8). A via hole (not shown in the figure) is provided in the planarization layer 46, and each anode 241 is electrically connected to one driving TFT through one via hole in the planarization layer 46. In some embodiments of this application, the anode 241 may be formed through in molding label (In Molding Label, IML).

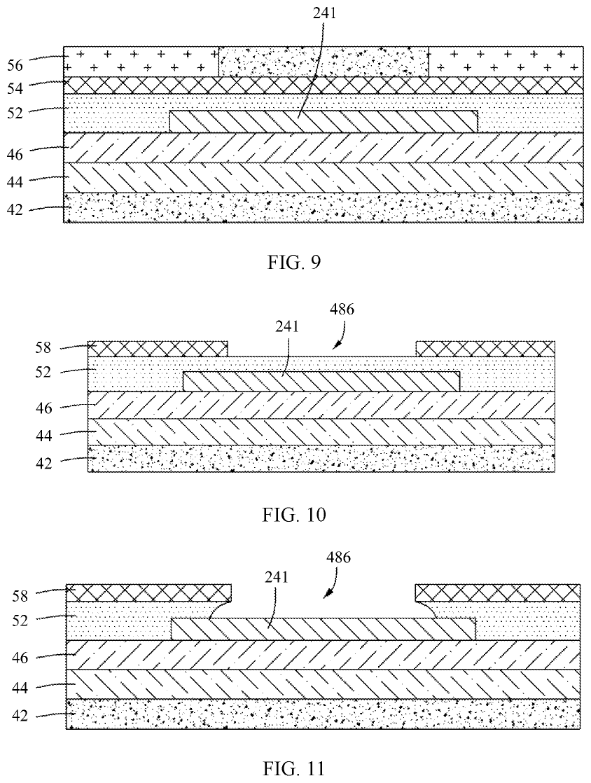

Step S12: Form a pixel define layer on the substrate and the anode. The following describes step S12 with reference to FIG. 9 to FIG. 13.

As shown in FIG. 9, Step S12 includes: forming a first material layer 52, a hard mask (Hard Mask) layer 54, and a patterned photoresist layer 56 on the substrate 42 and the anode 241. The first material layer 52 may be an organosiloxane, and is used to subsequently form the first pixel define layer 482. The hard mask layer 54 is, for example, ITO. The hard mask layer 54 may alternatively be another material, for example, silicon nitride, silicon oxide, or aluminum oxide.

As shown in FIG. 10, the patterned photoresist layer 56 in FIG. 9 is used as a mask, and the hard mask layer 54 is etched to obtain a patterned hard mask layer 58. The patterned hard mask layer 58 exposes a part of the first material layer 52. In some embodiments, the step of etching the hard mask layer 54 may be performing wet etching on the ITO.

As shown in FIG. 11, the patterned hard mask layer 58 is used as a mask to process the first material layer 52. A pixel defining hole 486 that exposes the anode 241 is formed in the first material layer 52, and an undercut is formed in the first material layer 52 at the pixel defining hole 486. Specifically, ashing processing may be performed on the first material layer 52 by using CL₂/O₂ plasma, and an etching parameter may be adjusted, so as to form a required undercut in the first material layer 52, to obtain the first pixel define layer 482.

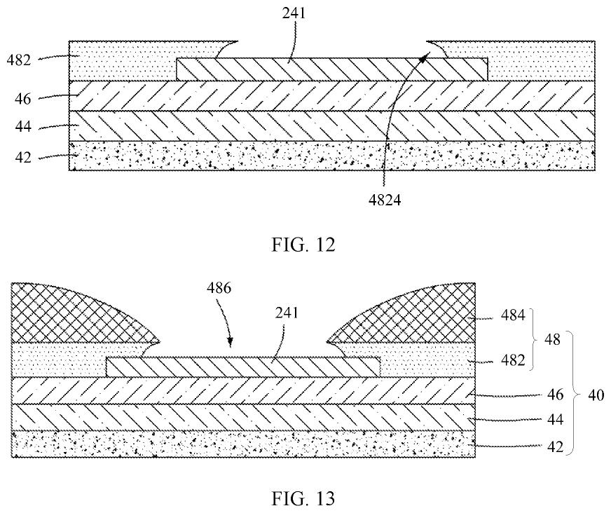

As shown in FIG. 12, after the first pixel define layer 482 is formed, the patterned hard mask layer 58 is removed. An undercut forms a recessed part 4824 of the first pixel define layer 482.

As shown in FIG. 13, the second pixel define layer 484 is formed on the first pixel define layer 482. The pixel defining hole 486 extends through the second pixel define layer 484, and the second pixel define layer 484 includes a top surface 4842 connected to the side surface 4822 of the first pixel define layer 482. The top surface 4842 includes a curved surface. An included angle θ (denoted in FIG. 5) between the curved surface and the upper surface that is of the anode 241 and that is away from the substrate 42 ranges from 5 degrees˜30 degrees. In some embodiments, the included angle θ between the curved surface and the upper surface that is of the anode 241 and that is away from the substrate 42 is less than or equal to 15 degrees. The second pixel define layer 484 may be formed by using organosiloxane. This step further includes performing ashing processing on the anode 241 by using oxidation plasma, so as to clear light resistance at the undercut position (also referred to as a chamfer position). The first pixel define layer 482 and the second pixel define layer 484 constitute the pixel define layer 48. Each pixel defining hole 486 exposes one anode 241.

Step S13: Form blocked common layers on the pixel define layer and the anode.

After the pixel define layer is formed, step S13 includes successively forming a hole inject layer, a hole transfer layer, an organic light emitting layer, a hole block layer, an electron transfer layer, and a cathode layer on the pixel define layer and the plurality of anodes. The hole inject layer, the hole transfer layer, the hole block layer, the electron transfer layer, and the cathode layer are all common layers, and are functional layers simultaneously deposited on/covering the subpixels (for example, R/G/B). In addition, for an OLED structure with a plurality of organic light emitting layers, the organic light emitting layers further include an electron-hole pair secondary generation layer located between two adjacent organic light emitting layers. The common layers include the electron-hole pair secondary generation layer.

In some embodiments of this application, the structure of the pixel define layer 48 enables at least one of the foregoing common layers to be blocked by the pixel define layer 48. The blocked common layer includes one or more of the hole inject layer, the hole transfer layer, the hole block layer, the electron transfer layer, and the electron-hole pair secondary generation layer, but do not include the cathode layer. That is, the cathode layer is a continuous film layer. The blocked common layer includes a part that is located on each anode 241 and that is used to form a portion of the OLED 24 and a blocking part that is located on the pixel define layer 48. The part that is of the blocked common layer and that is located on the anode 241 and the blocking part that is located on the pixel define layer 48 are spaced and insulated due to the pixel define layer 48.

Because a part that is of the blocked common layer and that is on each anode 241 and a part that is of the blocked common layer and that is on the pixel define layer 48 are interrupted, parts that are of the blocked common layer and that are on adjacent anodes 241 are also insulated and spaced. In other words, two adjacent subpixels are defined as a first subpixel and a second subpixel. It is defined that an OLED included in the first subpixel is a first OLED, and an OLED included in the second subpixel is a second OLED. It is defined that an anode of the first OLED is a first anode, and an anode of the second OLED is a second anode. The pixel define layer 48 exposes the first anode and the second anode. The blocked common layer includes a first part that is located on the first anode and that is used to form a portion of the first OLED, a second part that is located on the second anode and that is used to form a portion of the second OLED, and a blocking part that is located on the pixel define layer 48 and that is formed due to the pixel define layer 48. The first part and the second part are insulated and spaced from each other by the blocking part. In this way, at least a part of the common layers of the OLEDs in the two adjacent subpixels is blocked, so that a lateral current leakage at the common layers between the adjacent subpixels is reduced, a problem of light emission crosstalk of the display panel is alleviated, and display quality is improved.

The foregoing embodiments are only intended for describing the technical solutions of this application but not for limiting this application. Although this application is described in detail with reference to the preferred embodiments, a person of ordinary skill in the art should understand that modifications or equivalent replacements can be made to the technical solutions of this application without departing from the spirit and essence of the technical solutions of this application.

1. A display panel, comprising:
a substrate;
a first subpixel and a second subpixel that are adjacent and are disposed on the substrate, wherein the first subpixel comprises a first organic light emitting diode, the second subpixel comprises a second organic light emitting diode, the first organic light emitting diode comprises a first anode located on the substrate, and the second organic light emitting diode comprises a second anode located on the substrate;
a pixel define layer, located on the substrate, on the first anode, and on the second anode, wherein the pixel define layer has pixel defining holes that expose the first anode and the second anode; and
a common layer, wherein the common layer comprises a first part located on the first anode, a second part located on the second anode, and a blocking part that is located on the pixel define layer and that is formed due to the pixel define layer; wherein
the first part forms a portion of the first organic light emitting diode, the second part forms a portion of the second organic light emitting diode, and the first part and the second part are insulated and spaced from each other by using the blocking part.

2. The display panel according to claim 1, wherein the pixel define layer comprises a top surface away from the substrate and a side surface connected to the top surface, and the side surface comprises a recessed part, so that the blocking part is formed in the common layer.

3. The display panel according to claim 2, wherein the pixel define layer comprises a first pixel define layer and a second pixel define layer that are successively stacked in a direction away from the substrate, the recessed part is formed at the first pixel define layer, and the top surface is formed at the second pixel define layer.

4. The display panel according to claim 3, wherein the top surface comprises a curved surface connected to the side surface, and an included angle between the curved surface and a surface of the substrate ranges from 5 degrees˜30 degrees.

5. The display panel according to claim 1, wherein the display panel comprises a hole inject layer, a hole transfer layer, an organic light emitting layer, a hole block layer, and an electron transfer layer that are successively stacked in a direction away from the substrate, and the common layer comprises one or more of the hole inject layer, the hole transfer layer, the hole block layer, and the electron transfer layer.

6. The display panel according to claim 5, wherein the hole inject layer is in direct contact with the pixel define layer, the first anode, and the second anode;
a height from a surface that is of the first pixel define layer and that is away from the substrate to a surface that is of the first anode and that is away from the substrate is defined as h;
a sum of heights of the hole inject layer and the hole transfer layer is defined as h_{L}; and
a sum of heights of the hole inject layer, the hole transfer layer, the organic light emitting layer, the hole block layer, and the electron transfer layer is defined as h_{H}; wherein
h_{L}≤h≤h_{H}.

7. The display panel according to claim 6, wherein the organic light emitting layer comprises a first organic light emitting layer, an electron-hole pair secondary generation layer, and a second organic light emitting layer that are successively stacked in a direction away from the substrate, and the common layer comprises the electron-hole pair secondary generation layer.

8. The display panel according to claim 1, wherein the display panel further comprises a cathode layer located on a side that is of the common layer and that is away from the substrate, and the cathode layer is a continuous film layer.

9. A display panel, comprising:
a substrate;
a plurality of organic light emitting diodes that are disposed on the substrate at intervals, wherein each of the organic light emitting diodes comprises one anode;
a pixel define layer, located on the substrate and the anode, wherein the pixel define layer has a plurality of pixel defining holes, and each of the pixel defining holes exposes one anode; and
a common layer, comprising a part on the anode and a part on the pixel define layer; wherein
the pixel define layer comprises a first pixel define layer and a second pixel define layer that are successively stacked in a direction away from the substrate, and
a side surface of the first pixel define layer comprises a recessed part that is recessed relative to the second pixel define layer, so that a part that is of the common layer and that is on the anode is blocked from a part that is of the common layer and that is on the pixel define layer.

10. The display panel according to claim 9, wherein the second pixel define layer comprises a curved surface connected to the side surface, and an included angle between the curved surface and a surface of the substrate ranges from 5 degrees˜30 degrees.

11. The display panel according to claim 9, wherein the display panel comprises a hole inject layer, a hole transfer layer, an organic light emitting layer, a hole block layer, and an electron transfer layer that are successively stacked in a direction away from the substrate, and the common layer comprises one or more of the hole inject layer, the hole transfer layer, the hole block layer, and the electron transfer layer.

12. The display panel according to claim 11, wherein the hole inject layer is in direct contact with the pixel define layer and the anode;
a height from a surface that is of the first pixel define layer and that is away from the substrate to a surface that is of the anode and that is away from the substrate is defined as h;
a sum of heights of the hole inject layer and the hole transfer layer is defined as h_{L}; and
a sum of heights of the hole inject layer, the hole transfer layer, the organic light emitting layer, the hole block layer, and the electron transfer layer is defined as h_{H}; wherein
h_{L}≤h≤h_{H}.

13. The display panel according to claim 12, wherein the organic light emitting layer comprises a first organic light emitting layer, an electron-hole pair secondary generation layer, and a second organic light emitting layer that are successively stacked in a direction away from the substrate, and the common layer comprises the electron-hole pair secondary generation layer.

14. The display panel according to claim 9, wherein the display panel further comprises a cathode layer located on a side that is of the common layer and that is away from the substrate, and the cathode layer is a continuous film layer.

15. (canceled)

16. A preparation method for a display panel, comprising:
forming a plurality of anodes arranged in an array on a substrate, wherein the plurality of anodes comprise a first anode and a second anode that are adjacent;
forming a pixel define layer on the substrate and the plurality of anodes, wherein the pixel define layer has pixel defining holes that expose the first anode and the second anode; and
forming a common layer on the pixel define layer and the plurality of anodes, wherein the common layer comprises a first part on the first anode, a second part on the second anode, and a blocking part that is on the pixel define layer and that is formed due to the pixel define layer, and the first part and the second part are insulated and spaced from each other by using the blocking part; wherein
the first part is used to form a portion of a first organic light emitting diode, the second part is used to form a portion of a second organic light emitting diode, the first organic light emitting diode comprises the first anode, and the second organic light emitting diode comprises the second anode.

17. The preparation method for a display panel according to claim 16, wherein the pixel define layer comprises a top surface away from the substrate and a side surface connected to the top surface, and forming the pixel define layer comprises forming a recessed part on the side surface.

18. The preparation method for a display panel according to claim 17, wherein forming the pixel define layer comprises successively forming a first pixel define layer and a second pixel define layer that are stacked in a direction away from the substrate; and the recessed part is formed at the first pixel define layer, and the top surface is formed at the second pixel define layer.

19. The preparation method for a display panel according to claim 18, wherein the preparation method comprises successively forming a hole inject layer, a hole transfer layer, an organic light emitting layer, a hole block layer, and an electron transfer layer that are stacked in a direction away from the substrate; and forming the common layer comprises forming one or more of the hole inject layer, the hole transfer layer, the hole block layer, and the electron transfer layer.

20. The preparation method for a display panel according to claim 19, wherein forming the organic light emitting layer comprises successively forming a first organic light emitting layer, an electron-hole pair secondary generation layer, and a second organic light emitting layer in a direction away from the substrate; and forming the common layer comprises forming the electron-hole pair secondary generation layer.
